(19) United States
(12) Patent Application Publication
(10) Pub. No.: US 2024/0395324 A1
(43) Pub. Date: Nov. 28, 2024

(54) MEMORY DEVICE AND MANUFACTURING METHOD OF THE MEMORY DEVICE

(71) Applicant: SK hynix Inc., Icheon-si Gyeonggi-do (KR)

(72) Inventors: Seok Min CHOI, Icheon-si Gyeonggi-do (KR); Jung Shik JANG, Icheon-si Gyeonggi-do (KR); Rho Gyu KWAK, Icheon-si Gyeonggi-do (KR); Jeong Hwan KIM, Icheon-si Gyeonggi-do (KR); In Su PARK, Icheon-si Gyeonggi-do (KR); Won Geun CHOI, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 18/504,014

(22) Filed: Nov. 7, 2023

(30) Foreign Application Priority Data
May 26, 2023 (KR) 10-2023-0068232

(51) Int. Cl. G11C 16/04; G11C 5/06; H10B 43/10; H10B 43/27

(52) U.S. Cl. CPC G11C 16/0483; G11C 5/063; H10B 43/10; H10B 43/27

(57) ABSTRACT

A memory device includes: a memory cell array including a plurality of cell plugs; a first slit isolating the memory cell array into a plurality of memory regions, the first slit extending in a first direction; and second slits penetrating the plurality of memory regions, the second slits being arranged to be spaced apart from each other in a second direction intersecting the first direction. Gate lines included in each of the plurality of memory regions may be isolated from each other by the first slit. Each gate line located in the same layer among the gate lines included in each of the plurality of memory regions may extend through a first connection region between the second slits for each corresponding memory region.

### CROSS-REFERENCE TO RELATED APPLICATION

The present application claims priority under 35 U.S.C. § 119(a) to Korean patent application number 10-2023-0068232 filed on May 26, 2023, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device including a memory block having a three-dimensional structure and a manufacturing method of the memory device.

### 2. Related Art

A memory device may include a nonvolatile memory device in which stored data is retained as it is even when power supply is interrupted. The nonvolatile memory device may be divided into a two-dimensional structure and a three-dimensional structure according to a structure in which memory cells are arranged. Memory cells of a nonvolatile memory device having a two-dimensional structure may be arranged in a single layer above a substrate, and memory cells of a non-volatile memory device having a three-dimensional structure may be stacked in a vertical direction above a substrate. Because a degree of integration of the nonvolatile memory device having the three-dimensional structure is higher than a degree of integration of the nonvolatile memory device having the two-dimensional structure, electronic devices using the nonvolatile memory device having the three-dimensional structure have recently been increasingly used.

### SUMMARY

In accordance with an embodiment of the present disclosure, there may be provided a memory device including: a memory cell array including a plurality of cell plugs; a first slit isolating the memory cell array into a plurality of memory regions, the first slit extending in a first direction; and second slits penetrating the plurality of memory regions, the second slits being arranged to be spaced apart from each other in a second direction intersecting the first direction, wherein gate lines included in each of the plurality of memory regions are isolated from each other by the first slit, and wherein each gate line located in the same layer among the gate lines included in each of the plurality of memory regions extends through a first connection region between the second slits for each corresponding memory region.

In accordance with an embodiment of the present disclosure, there may be provided a method of manufacturing a memory device, the method including: forming a stack structure in which first material layers and second material layers are alternately stacked; forming cell plugs penetrating the stack structure; forming first slit trenches isolating the stack structure along a first direction and second slit trenches which are spaced apart from each other in a second direction intersecting the first direction between the first slit trenches and penetrate the stack structure; removing the second material layers exposed through the first slit trenches and the second slit trenches; forming conductive layers in regions between the first material layers, in which the second material layers are removed; and forming a slit material layer in the first and second slit trenches.

In accordance with an embodiment of the present disclosure, there may be provided a memory device including: a memory cell array including a plurality of cell plugs; a first slit isolating the memory cell array into a plurality of memory regions, the first slit extending in a first direction; and a second slit penetrating the plurality of memory regions, the second slit having a plane including a minor axis in the first direction and a major axis in a second direction intersecting the first direction, wherein gate lines included in each of the plurality of memory regions are isolated from each other by the first slit, and wherein each gate line located in the same layer among the gate lines included in each of the plurality of memory regions extends through a connection region between the first slit and the second slit for each corresponding memory region.

### BRIEF DESCRIPTION OF THE DRAWINGS

Examples of embodiments will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. Like reference numerals refer to like elements throughout.

FIG. 1 is a diagram illustrating an embodiment of a memory device.

FIG. 2 is a diagram illustrating an embodiment of a memory cell array.

FIG. 3 is a diagram illustrating an embodiment of a memory block.

FIGS. 4A, 4B, 4C, 4D, and 4E are views illustrating a structure of a memory device in accordance with a first embodiment of the present disclosure.

FIGS. 5A, 5B, 5C, and 5D are sectional views illustrating a manufacturing method of the memory device in accordance with the first embodiment of the present disclosure.

FIGS. 6A, 6B, 6C, and 6D are views illustrating a structure of a memory device in accordance with a second embodiment of the present disclosure.

FIGS. 7A, 7B, 7C, and 7D are views illustrating a structure of a memory device in accordance with a third embodiment of the present disclosure.

FIG. 8 is a diagram illustrating an embodiment of a memory card system to which the memory device of the present disclosure is applied.

FIG. 9 is a diagram illustrating an embodiment of a Solid State Drive (SSD) system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout.

Hereinafter, embodiments of the present disclosure will be described in detail with reference to the accompanying drawings in order for those skilled in the art to be able to readily implement the technical spirit of the present disclosure.

Embodiments provide a memory device and a manufacturing method of the memory device, which can prevent or mitigate warpage of a memory block.

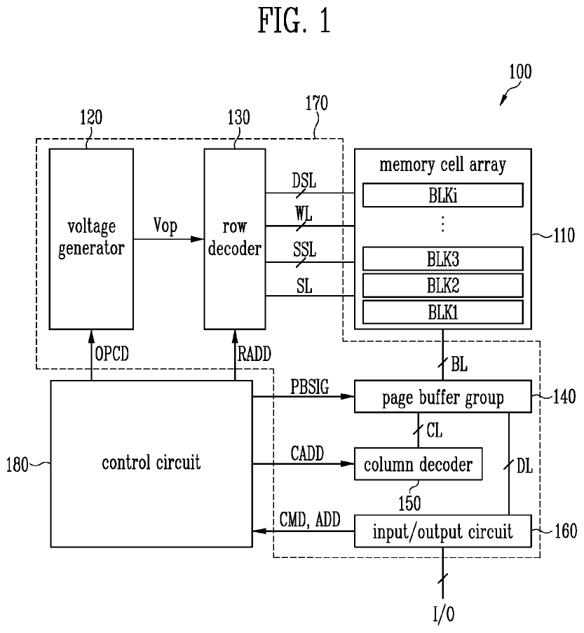

FIG. 1 is a diagram illustrating a memory device.

Referring to FIG. 1, the memory device 100 may include a memory cell array 110, a peripheral circuit 170, and a control circuit 180.

The memory cell array 110 may include first to ith memory blocks BLK1 to BLKi (i is a positive integer). Each of the first to ith memory blocks BLK1 to BLKi may include memory cells capable of storing data. Drain select lines DSL, word lines WL, source select lines SSL, and a source line SL may be connected to each of the first to ith memory blocks BLK1 to BLKi, and bit lines BL may be commonly connected to the first to ith memory blocks BLK1 to BLKi.

In the present disclosure, a memory region may refer to a memory plane or a memory block. In the present disclosure, for convenience, a case where the memory region is the memory block is mainly described. However, the present disclosure is not limited thereto.

The first to ith memory blocks BLK1 to BLKi may be formed in a three-dimensional structure. The memory blocks having the three-dimensional structure may include memory cells stacked in a vertical direction above a substrate.

The memory cells may store one-bit or two-or-more-bit data according to a program manner. For example, a manner in which one-bit data is stored in one memory cell is referred to as a single level cell (SLC) manner, and a manner in which two-bit data is stored in one memory cells is referred to as a multi-level cell (MLC) manner. A manner in which three-bit data is stored in one memory cell is referred to as a triple level cell (TLC) manner, and a manner in which four-bit data is stored in one memory cell is referred to as a quad level cell (QLC) manner. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 is configured to generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages are voltages applied to a selected word line among word lines WL in a program operation, and may be used to increase a threshold voltage of memory cells connected to the selected word line. The turn-on voltages may be applied to the drain select lines DSL or the source select lines SSL, and be used to turn on drain select transistors or source select transistors. The turn-off voltages may be applied to the drain select lines DSL or the source select lines SSL, and be used to turn off the drain select transistors or the source select transistors. For example, the turn-off voltage may be set to 0V. The precharge voltages are voltages higher than 0V, and may be applied to the bit lines in a read operation. The verify voltages may be used in a verify operation for determining whether a threshold voltage of selected memory cells has been increased to a target level. The verify voltages may be set to various levels according to the target level, and be applied to a selected word line.

The read voltages may be applied to a selected word line in a read operation of selected memory cells. For example, the read voltages may be set to various levels according to a program manner of the selected memory cells.

The pass voltages are voltages applied to unselected word lines among the word lines WL in a program or read operation, and may be used to turn on memory cells connected to the unselected word lines. In the read operation in accordance with this embodiment, the pass voltages may include a target pass voltage set highest and sub-pass voltages lower than the target pass voltage. For example, before a read voltage is applied to a selected word line, the sub-pass voltages may be applied to adjacent word lines adjacent to the selected word line. When the sub-pass voltages are applied to the adjacent word lines, the target pass voltage may be applied to the other unselected word lines. When the read voltage is applied to the selected word line, the target pass voltage may be applied to the adjacent word lines.

The erase voltages may be used in an erase operation for erasing memory cells included in a selected memory block, and be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines, and may be connected to the first to ith memory blocks BLK1 to BLKi through the drain select lines DSL, the word lines WL, the source select lines SSL, and the source line SL.

The page buffer group 140 may include page buffers (not shown) connected to each of the first to ith memory blocks BLK1 to BLKi. The page buffers (not shown) may be connected to the first to ith memory blocks BLK1 to BLKi respectively through the bit lines BL. In a read operation, the page buffers (not shown) may sense a current or a voltage of the bit lines BL, which varies according to threshold voltages of selected memory cells, and store sensed data, in response to page buffer control signals PBSIG.

The column decoder 150 may be configured to transmit data between the page buffer group 140 and the input/output circuit 160 in response to a column address CADD. For example, the column decoder 150 may be connected to the page buffer group 140 through column lines CL, and transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit, to the control circuit 180, a command CMD and an address ADD, which are received from an external controller, through the input/output lines I/O, and transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output at least one of an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation of the selected memory block selected and output read data. When the command CMD input to the control circuit 180 is a command corresponding to an erase operation, the control circuit 180 may control the peripheral circuit 170 to perform the erase operation of the selected memory block.

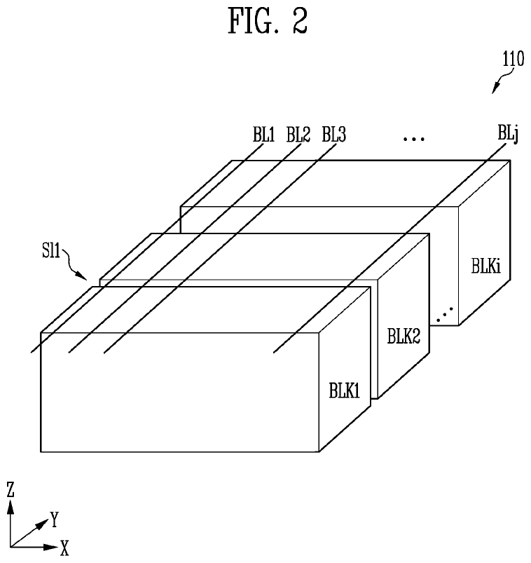

FIG. 2 is a diagram illustrating a memory cell array.

Referring to FIG. 2, the memory cell array 110 may include first to ith memory blocks BLK1 to BLKi. The first to ith memory blocks BLK1 to BLKi may be arranged to be spaced apart from each other along a Y direction.

The first to ith memory blocks BLK1 to BLKi may be commonly connected to a first to jth bit lines BL1 to BLj. For example, the first to jth bit lines BL1 to BLj may extend along the Y direction, and be arranged to be spaced apart from each other along an X direction.

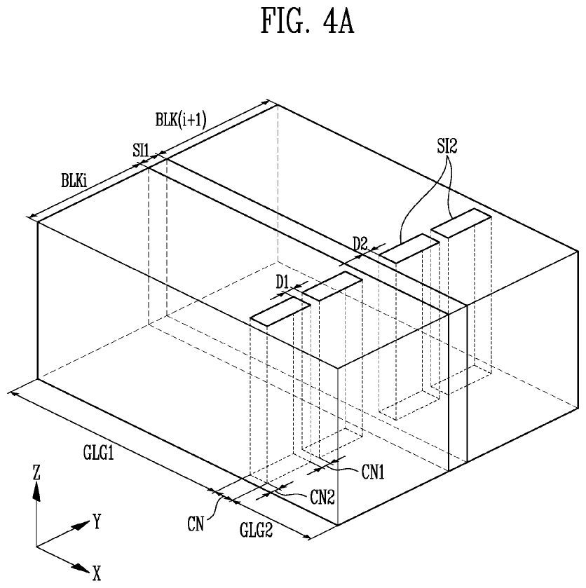

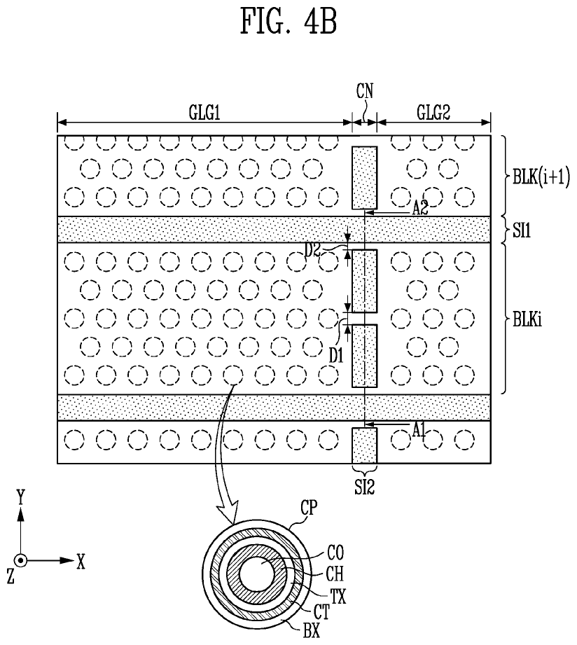

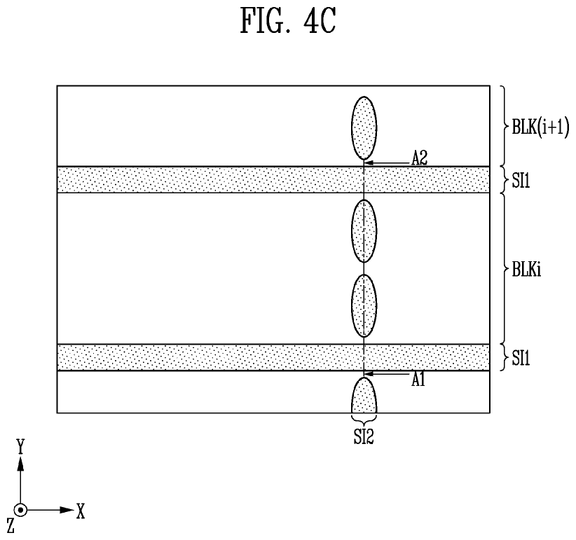

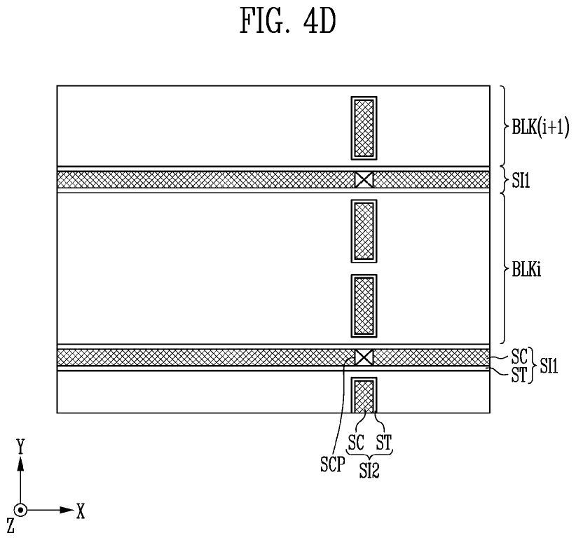

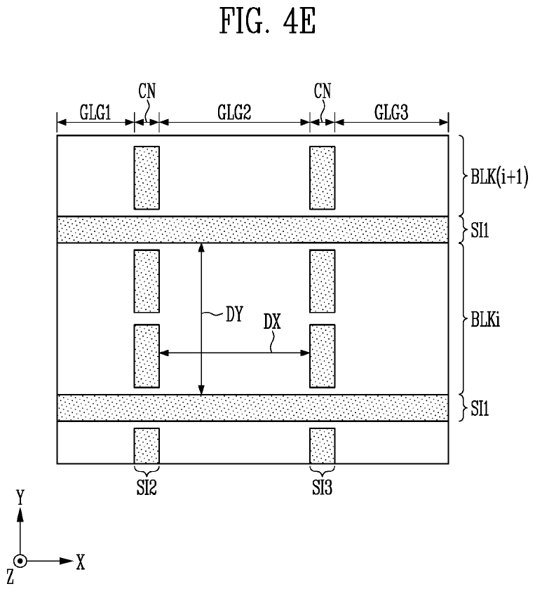

The first to ith memory blocks BLK1 to BLKi may be isolated from each other by first slits SI1. The first slit SI1 may isolate the memory cell array 110 into a plurality of memory blocks (e.g., the first to ith memory blocks BLK1 to BLKi). The first slit SI1 will be additionally described later with reference to FIG. 4.

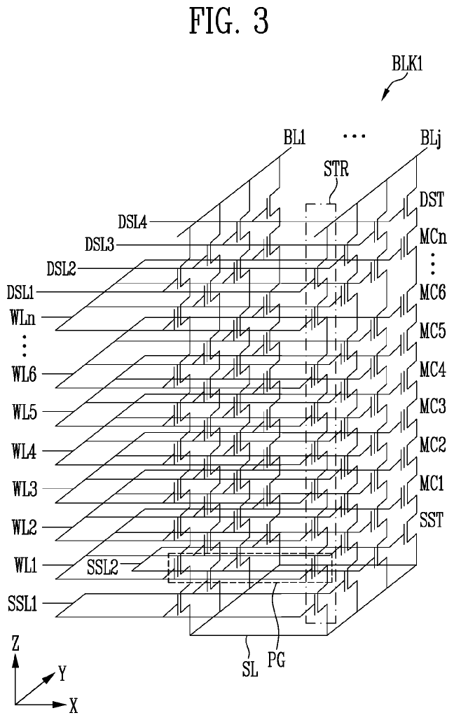

FIG. 3 is a diagram illustrating a memory block.

Referring to FIG. 3, a first memory block BLK1 may include strings STR connected between first to jth bit lines BL1 to BLj and a source line SL. The first to jth bit lines BL1 to BLj extend along the Y direction and are arranged to be spaced apart from each other along the X direction. Therefore, the strings STR may be arranged to be spaced apart from each other along the X and Y directions. For example, strings STR may be connected between the first bit line BL1 and the source line SL, and strings STR may be arranged between the second bit line BL2 and the source line SL. In this manner, strings STR may be arranged between the jth bit line BLj and the source line SL. The strings STR may extend along a Z direction.

Any one string STR among strings STR connected to the jth bit line BLj will be described as an example. The string STR may include a source select transistor SST, first to nth memory cells MC1 to MCn, and a drain select transistor DST. The first memory block BLK1 shown in FIG. 3 is a diagram schematically illustrating a structure of a memory block, and therefore, numbers of source select transistors SST, first to nth memory cells MC1 to MCn, and drain select transistors DST, which are included in the strings STR, may vary according to a memory device.

Gates of source select transistors SST included in different strings STR may be connected to a first or second source select line SSL1 or SSL2, gates of first to nth memory cells MC1 to MCn included in the different strings STR may be connected to first to nth word lines WL1 to WLn, and each of gates of drain select transistors DST included in the different strings STR may be connected to any one of first to fourth drain select lines DSL1 to DSL4.

The lines connected to the first memory block BLK1 will be described in detail. Source select transistors SST arranged along the X direction may be connected to the same source select line, and source select transistors SST arranged along the Y direction may be connected to source select lines isolated from each other. For example, some of the source select transistors SST arranged in the Y direction may be connected to the first source select line SSL1, and the others of the source select transistors SST arranged in the Y direction may be connected to the second source select line SSL2. The second source select line SSL2 is a line isolated from the first source select line SSL1. Therefore, a voltage applied to the first source select line SSL1 may be equal to or different from a voltage applied to the second source select line SSL2.

Memory cells formed in the same layer among the first to nth memory cells MC1 to MCn may be connected to the same word line. For example, first memory cells MC1 included in different strings STR may be commonly connected to the first word line WL1, and nth memory cells MCn included in the different strings STR may be commonly connected to the nth word line WLn. A group of memory cells which are included in different strings STR and are connected to the same word line may be designated as a page PG. Program and read operations may be performed in units of pages PG, and an erase operation may be performed in units of memory blocks. An operation performed in units of memory blocks may be performed on all pages included in a selected memory block.

Drain select transistors DST arranged in the Y direction may be connected to the first to fourth drain select lines DSL1 to DSL4 isolated from each other. Specifically, drain select transistors DST arranged along the X direction may be connected to the same drain select line, and drain select transistors DST arranged along the Y direction may be connected to the first to fourth drain select lines DSL1 to DSL4 isolated from each other. Because the first to fourth drain select lines DSL1 to DSL4 are isolated from each other, different voltages may be applied to the first to fourth drain select lines DSL1 to DSL4.

FIGS. 4A to 4E are views illustrating a structure of a memory device in accordance with a first embodiment of the present disclosure. FIG. 4A is a perspective view illustrating first slits SI1 and second slits SI2, which are included in the memory device in accordance with the first embodiment of the present disclosure. FIG. 4B is a plan view illustrating a layout of the second slits SI2 shown in FIG. 4A. FIG. 4C is a plan view illustrating various shapes of second slits SI2. FIG. 4D is a plan view illustrating an example in which each of the first slits SI1 and second slits SI2 is formed as a multi-layer. FIG. 4E is a plan view illustrating a layout of the memory device which further includes third slits SI3 together with the first slits SI1 and the second slits SI2.

Referring to FIG. 4A, an ith memory block BLKi and an (i+1) th memory block BLK (i+1) may be isolated from each other by a first slit SI1. The first slit SI1 formed between the ith memory block BLKi and the (i+1) th memory block BLK (i+1) may be formed in a vertical direction (e.g., the Z direction) from a substrate (not shown), and extend in a first direction (e.g., the X direction).

Because the ith memory block BLKi and the (i+1) th memory block BLK (i+1) are isolated from each other by the first slit SI1, gate lines included in different memory blocks may be isolated from each other by the first slit SI1. For example, gate lines included in the ith memory block BLKi may be isolated from gate lines included in the (i+1) th memory block BLK (i+1) by the first slit SI1.

Second slits SI2 included in the ith memory block BLKi and the (i+1) th memory block BLK (i+1) may penetrate the ith and (i+1) th memory blocks BLKi and BLK (i+1) between first slits SI1. The second slits SI2 may be formed in the vertical direction (e.g., the Z direction) from the substrate (not shown), to penetrate the ith and (i+1) th memory blocks BLKi and BLK (i+1). The first slit SI1 and the second slits SI2, which penetrate the ith memory block BLKi and the (i+1) th memory block BLK (i+1) in the vertical direction (e.g., the Z direction) may have the same depth. Two or more second slits SI2 disposed in alignment with each other along a second direction (e.g., the Y direction) may be formed in one memory block (e.g., the ith memory block BLKi).

The second slits SI2 may be arranged to be spaced apart from each other in the second direction (e.g., the Y direction). For example, second slits SI2 penetrating the ith memory block BLKi may be spaced apart from each other at a first distance D1 in the second direction (e.g., the Y direction).

Because the second slits SI2 are arranged to be spaced apart from each other, each of gate lines located in the same layer among gate lines included in each of a plurality of memory blocks may extend through a first connection region CN1 between second slits SI2. For example, gate lines included in a first gate line group GLG1 among the gate lines included in the ith memory block BLKi may respectively extend to gate lines included in a second gate line group GLG2 among the gate lines included in the ith memory block BLKi through the first connection region CN1.

The second slits SI2 may be arranged to be spaced apart from the first slit SI1. For example, at least one of the second slits SI2 penetrating the ith and (i+1) th memory blocks BLKi and BLK (i+1) may be spaced apart from the first slit SI1 formed between the ith memory block BLKi and the (i+1) th memory block BLK (i+1) at a second distance D2 in the second direction (e.g., the Y direction).

Because the first slit SI1 and the second slits SI2 are arranged to be spaced apart from each other, each of gate lines located in the same layer among gate lines included in a plurality of memory blocks may extend through a second connection region CN2 between a first slit SI1 and second slits SI2. For example, the gate lines included in the first gate line group GLG1 among the gate lines included in the ith memory block BLKi may respectively extend to the gate lines included in the second gate line group GLG2 among the gate lines included in the ith memory block BLKi through the second connection region CN2. In the present disclosure, the second connection region CN2 between the first slit SI1 and the second slits SI2 may refer to a region between any one first slit SI1 and any one second slit SI2 most adjacent to the one first slit SI1 among the one first slit SI1 and second slits SI2.

Therefore, in the present disclosure, each of gate lines located in the same layer among gate lines included in each of a plurality of memory blocks may extend through the first connection region CN1 and the second connection region CN2. In the present disclosure, a connection region may be a region including the first connection region CN1 and the second connection region CN2. Therefore, gate lines located in the same layer among the gate lines included in the ith memory block BLKi may be electrically connected to each other through the first and second connection regions CN1 and CN2 included in the connection region CN.

In the present disclosure, for convenience of description, the first gate line group GLG1 and the second gate line group GLG2 refer to gate lines included in one memory blocks, which are divided with respect to the second slits SI2, and the gate lines might not be physically or electrically isolated from each other.

The second slits SI2 may be formed in a quadrangular pillar shape. A plane (e.g., a section viewed in the Z direction) of each of the second slits SI2 may include a minor axis in the first direction (e.g., the X direction) and a major axis in the second direction (e.g., the Y direction).

Referring to FIG. 4B, the ith and (i+1) th memory blocks BLKi and BLK (i+1) may include a plurality of cell plugs CP formed in the vertical direction (e.g., the Z direction) from the substrate (not shown).

Each of the cell plugs CP may include a blocking layer BX having a cylindrical shape, a charge trap layer CT formed along an inner wall of the blocking layer BX, a tunnel insulating layer TX formed along an inner wall of the charge trap layer CT, a channel layer CH formed along an inner wall of the tunnel insulating layer TX, and a core pillar CO formed in a circular pillar shape in a region surrounded by the channel layer CH. The blocking layer BX and the tunnel insulating layer TX may be formed of an oxide layer (e.g., a silicon oxide layer). The charge trap layer CT may be formed of a nitride layer. The channel layer CH may be formed of a doped silicon layer. The core pillar CO may be formed of an insulating layer or a conductive layer. The blocking layer BX, the charge trap layer CT, the tunnel insulating layer TX, the channel layer CH, and the core pillar CO, which are formed in the cell plug CT, may extend in the vertical direction (e.g., the Z direction). A capping layer for improving an electrical characteristic of drain select transistors DST may be further formed on the top of the core pillar CO.

Cell plugs CP included in the ith memory block BLKi may be configured with a plurality of rows. Each row may include cell plugs CP spaced apart from each other along the X direction. The plurality of rows may be spaced apart from each other along the Y direction. Centers of cell plugs CP included in an odd-numbered row and centers of cell plugs CP included in an even-numbered row may be offset from each other. For example, cell plugs CP adjacent to each other in the Y direction may be arranged in a zigzag form.

In addition, the cell plugs CP may be symmetrically or asymmetrically located with respect to the second slits SI2. For example, when a distance between a cell plug CP most adjacent to a second slit SI2 on a first row, which is included in the first gate line group GLG1, and the second slit SI2 is smaller than a distance between a cell plug CP most adjacent to the second slit SI2 on a second row, which is included in the first gate line group GLG1, and the second slit SI2, a distance between a cell plug CP most adjacent to the second slit SI2 on the first row, which is included in the second gate line group GLG2, and the second slit SI2 may be smaller than a distance between a cell plug CP most adjacent to the second slit SI2 on the second row, which is included in the second gate line group GLG2, and the second slit SI2. In another example, apart from what is shown in FIG. 4B, when a distance between a cell plug CP most adjacent to the second slit SI2 on the first row, which is included in the first gate line group GLG1, and the second slit SI2 is smaller than a distance between a cell plug CP most adjacent to the second slit SI2 on the second row, which is included in the first gate line group GLG1, and the second slit SI2, a distance between a cell plug CP most adjacent to the second slit SI2 on the first row, which is included in the second gate line group GLG2, and the second slit SI2 may be greater than a distance between a cell plug CP most adjacent to the second slit SI2 on the second row, which is included in the second gate line group GLG2, and the second slit SI2.

In addition, a size (e.g., an area of a section) of each of the cell plugs CP may vary according to a position. For example, the cell plugs CP included in the ith memory block BLKi may all be formed to the same size, and be formed to having different sizes according to distances from the second slit SI2. For example, each of cell plugs CP most adjacent to a second slit SI2 may be formed to a large area of a section thereof, as compared with the other cell plugs CP. Alternatively, each of cell plugs CP located within a certain distance from a second slit SI2 may be formed to have a large area of a section thereof, as compared with the other cell plugs CP that are not located within a certain distance from the second slit SI2.

The cell plugs CP may be variously formed in addition to the above-described embodiments with respect to the cell plugs CP. However, the scope of the present disclosure is not limited to the specific form of the cell plugs CP. In the drawings from FIG. 4B, for convenience of description, illustration of the cell plugs CP may be omitted.

The first slits SI1 and the second slits SI2 may include a slit material layer filled in a slit trench. The slit material layer may be formed as a single layer or a multi-layer. For example, the slit material layer may be an insulating layer or a silicon layer (e.g., amorphous silicon). In another example, the slit material layer may be a multi-layer including at least two layers. The first and second slits SI1 and SI2 each including a multi-layer will be described later with reference to FIG. 4D.

Referring to FIG. 4C, the other structures except a shape of the second slits SI2 are the same as the structures described with reference to FIG. 4B. Therefore, in FIG. 4C, descriptions of structures overlapping with those shown in FIG. 4 will be omitted or be briefly described. The second slits SI2 may be formed in a circular pillar shape. A plane of each of the second slits SI2 may be an ellipse including a minor axis in the first direction (e.g., the X direction) and a major axis in the second direction (e.g., the Y direction). In another embodiment, the second slits SI2 may be formed in various shapes in addition to the quadrangular pillar shape or the circular pillar shape. For example, the second slits SI2 may be formed to have a quadrangular plane having round corners. Hereinafter, for convenience of description, a case where the second slits SI2 have a quadrangular pillar shape is mainly illustrated or described.

Referring to FIG. 4D, each of slit material layers filling the first and second slits SI1 and SI2 may be formed as a multi-layer. The first slits SI1 may include slit insulating layers ST and slit conductive layers SC. The second slits SI2 may include slit insulating layers ST and slit conductive layers SC. The slit insulating layers ST included in the first slits SI1 and the slit insulating layers ST included in the second slits SI2 may be formed of the same material. In addition, the slit conductive layers SC included in the first slits SI1 and the slit conductive layers SC included in the second slits SI2 may be formed of the same material. In an embodiment, the slit conductive layer SC included in the first slit SI1 may be used as a source contact.

The slit conductive layers SC may be formed in the vertical direction (e.g., the Z direction) on a source line (not shown) formed on the bottom of memory blocks to be in contact with the source line (not shown). The slit conductive layers SC may be formed of a conductive material such as doped poly-silicon or tungsten. The slit insulating layers ST may be formed to surround the periphery of the slit conductive layers SC such that the slit conductive layers SC are electrically blocked from gate lines. The slit insulating layers ST may be formed of an oxide layer (e.g., a silicon oxide layer).

Source contact plugs SCP may be formed in the Z direction with respect to the slit conductive layers SC included in the first slits SI1. The source contact plugs SCP may be electrically connected to the source line (not shown) through the slit conductive layers SC included in the first slits SI1. The source contact plug SCP may be formed of a conductive material. For example, the source contact plug SCP may include at least one of a metal (e.g., tungsten, copper, aluminum or titanium), a conductive metal nitride, and a doped semiconductor.

The source contact plugs SCP may be disposed to be in alignment with each other in the second direction (e.g., the Y direction) with second slits SI2 interposed therebetween. For example, centers of the source contact plugs SCP and centers of the second slits SI2 may be arranged to be in alignment with each other in the second direction (e.g., the Y direction). For example, centers of the source contact plugs SCP and centers of the second slits SI2 may be arranged to be in alignment with each other in the second direction (e.g., the Y direction) as shown in FIG. 4D. However, the present disclosure is not limited thereto, and the second slits SI2 may be formed regardless of the positions of the source contact plugs SCP.

Although a case where the first slits SI1 have flat side surfaces is illustrated in FIGS. 4A to 4D, the shape of the first slits SI1 is not limited thereto. For example, as sidewalls of the first slits SI1 are not formed flat, widths of the first slits SI1 in the Y direction may be different from each other according to positions in the X direction.

In an embodiment, as a size of the memory blocks increases, tensile stresses in the X and Y directions, which are applied to each of the gate lines may increase. In an embodiment, the tensile stress in the Y direction, which is applied to each of the gate lines may be decreased by the first slits SI1, and the tensile stress in the X direction may be decreased by the second slits SI2.

Thus, in accordance with an embodiment of the present disclosure, a degree to which a wafer is warped can be decreased, and accordingly, defects which may occur in the memory device can be reduced. For example, in an embodiment, defects (e.g., an overlay, a crack, and bending) which may occur in manufacturing processes of the memory device are reduced, so that a manufacturing yield can be improved. Also, in accordance with an embodiment of the present disclosure, when the degree to which the wafer is warped is improved, a limitation in performing a subsequent process (e.g., a mask process) difficult to be performed as the wafer is warped can be reduced.

In addition, in an embodiment, when the second slits SI2 are formed in alignment with the source contact plugs SCP in the Y direction as shown in FIG. 4D, a cell density might not decrease as compared with the existing memory cells even when the select slits SI2 are formed.

Referring to FIG. 4E, the memory device may further include third slits SI3 penetrating a plurality of memory blocks. The third slits SI3 may be spaced apart from the second slits SI2 in the first direction (e.g., the X direction). Also, the third slits SI3 may be spaced apart from each other in the second direction (e.g., the Y direction).

In the present disclosure, descriptions of the second slits SI2 may be applied to the third slits SI3. For example, the third slits SI3 may be spaced apart from each other at the first distance D1 in the second direction (e.g., the Y direction). The third slits SI3 may be arranged to be spaced apart from the first slit SI1 at the second distance D2. The first distance D1 and the second distance D2 are corresponding to the first distance D1 and the second distance D2 shown in the FIG. 4B. A plane (e.g., an XY plane) of each of the third slits SI3 may include a minor axis in the first direction (e.g., the X direction) and a major axis in the second direction (e.g., the Y direction). The third slits SI3 may include a slit material layer (e.g., a single layer or a multi-layer).

In addition to the second slits SI2, the third slits SI3 may also be arranged to be spaced apart from each other, and hence each of gate lines located in the same layer among gate lines included in each of the plurality of memory blocks may extend through the connection region CN. In addition, the first slit SI1 and the third slits SI3 are arranged to be spaced apart from each other, and hence each of gate lines located in the same layer among gate lines included in each of the plurality of memory blocks may extend through a connection region CN between the first slit SI1 and the third slits SI3. Therefore, gate lines included in a first gate line group GLG1 among the gate lines included in the ith memory blocks BLKi, gate lines included in a second gate line group GLG2 among the gate lines included in the ith memory blocks BLKi, and gate lines included in a third gate line group GLG3 among the gate lines included in the ith memory blocks BLKi may extend to each other through connection regions CN (e.g., a connection region between the first slit SI1 and the second or third slits SI2 or SI3, a connection region between the second slits SI2, and a connection region between the third slits SI3).

In FIG. 4E, it is illustrated that the second slits SI2 and the third slits SI3 are included in the ith memory block BLKi. However, more slits may be formed in addition to the second slits SI2 and the third slits SI3. For example, additional second and third slits SI2 and SI3 may be periodically further formed in the X direction with respect to the third slits SI3.

In accordance with an embodiment shown in FIG. 4E, the tensile stress in the X direction, which is applied to each of the gate lines, can be further decreased as compared with the embodiments shown in FIGS. 4A to 4D. In an embodiment, the tensile stress in the X direction, which is applied to each of the gate lines, can be decreased by not only the second slits SI2 but also the third slits SI3. For example, as a distance DX between the second slits SI2 and the third slits SI3 becomes more similar to a distance DY between the first slits SI1, the tensile stress in the X direction, which is applied to the gate line, becomes more similar to the tensile stress in the Y direction, which is applied to the gate line. Therefore, in an embodiment, the warpage of the wafer can be reduced.

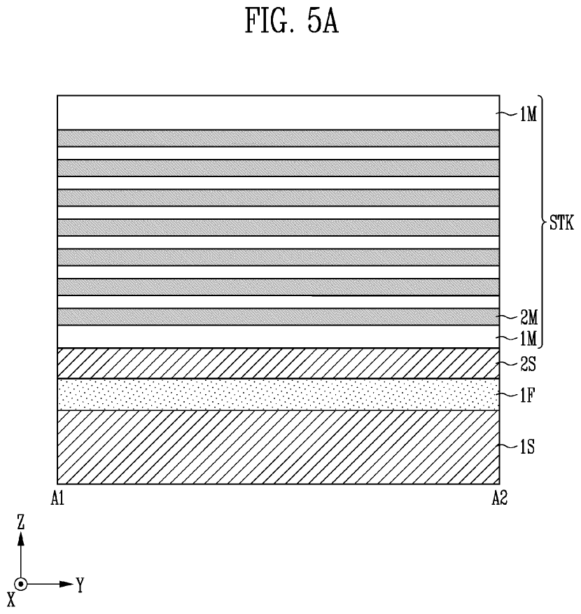

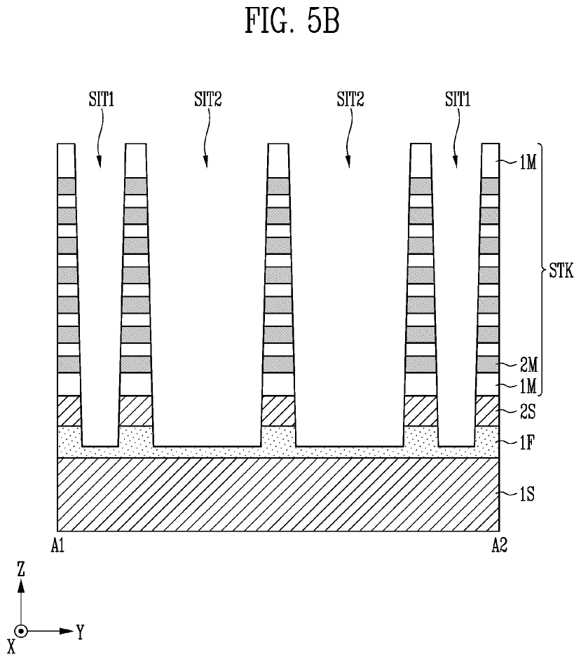

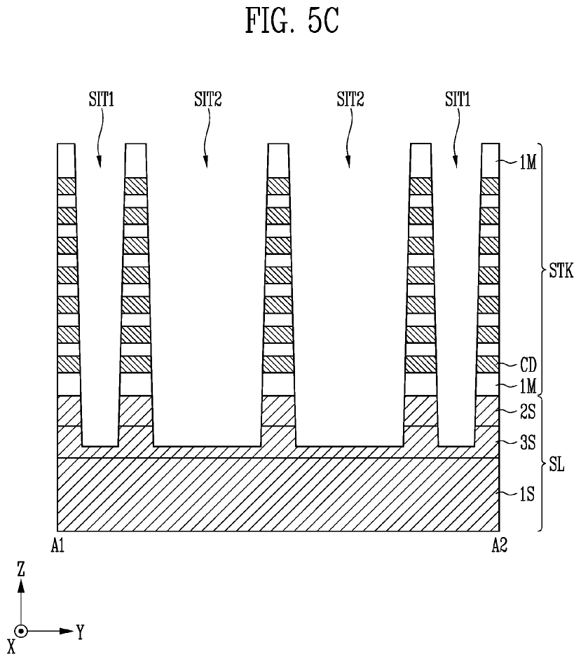

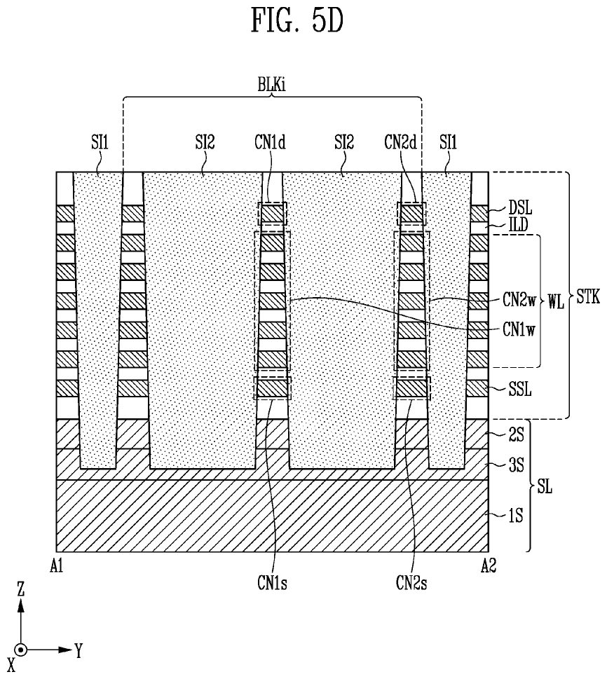

FIGS. 5A to 5D are sectional views illustrating a manufacturing method of the memory device in accordance with the first embodiment of the present disclosure. In FIGS. 5A to 5D, a section of the memory device taken along line A1-A2 shown in FIG. 4B or 4C is illustrated.

Referring to FIG. 5A, a first source layer 1S, a first sacrificial layer 1F, and a second source layer 2S may be stacked on a lower structure (not shown). The lower structure (not shown) may be a structure including a substrate or peripheral circuits. Because the first source layer 1S is a layer used as a source line, the first source layer 1S may be formed of a conductive material. For example, the first source layer 1S may be formed of a conductive material such as poly-silicon, tungsten or nickel. The first sacrificial layer 1F may be formed of a material having an etch selectivity different from an etch selectivity of the first source layer 1S. The second source layer 2S may be formed of the same material as the first source layer 1S. Although not shown in the drawing, a buffer layer may be further formed between the first source layer 1S and the first sacrificial layer 1F and between the second source layer 2S and the first sacrificial layer 1F to protect the first source layer 1S and the second source layer 2S in a subsequent process. For example, the buffer layer may be formed of an oxide layer.

Subsequently, a stack structure STK may be formed, in which first material layers 1M and second material layers 2M are alternately stacked. The first and second material layers 1M and 2M may be alternately stacked on the top of the second source layer 2S. For example, when a first material layer 1M is formed on the top of the second source layer 2S, a second material layer 2M may be formed on the top of the first material 1M, and a first material layer 1M may be formed on the top of the second material layer 2M. The first material layer 1M may be formed of an insulating material. For example, the first material layer 1M may be formed of an oxide layer (e.g., a silicon oxide layer). The second material layer 2M may be formed of a material which can be selectively removed in a subsequent process. Therefore, the second material layer 2M may be formed of a material having an etch selectivity different from an etch selectivity of the first material layer 1M. For example, the second material layer 2M may be formed of a nitride layer. The first material layer 1M may be formed at a lowermost end and an uppermost end in the stack structure STK in which the first and second material layers 1M and 2M are stacked.

Referring to FIG. 5B, there may be formed first slit trenches SIT1 isolating the stack structure STK along the first direction (e.g., the X direction) and second slit trenches SIT2 penetrating the stack structure STK between the first slit trenches SIT1. The second slit trenches SIT2 may be formed to be spaced apart from each other in the second direction (e.g., the Y direction). Also, the second slit trenches SIT2 may be formed to be spaced apart from the first slit trenches SIT1.

The first slit trenches SIT1 and the second slit trenches SIT2 may be formed to the same depth. For example, the first slit trenches SIT1 and the second slit trenches SIT2 may be simultaneously formed through an etching process for regions in which first slits SI1 and second slits SI2 are to be formed. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

In relation to FIGS. 5A and 5B, after the stack structure STK is formed, cell plugs (not shown) may be formed, which penetrate the stack structure in the Z direction. For example, cell plugs CP may be formed at the positions shown in FIG. 4B, and the first and second slit trenches SIT1 and SIT2 may be formed after the cell plugs CP are formed. In an example, cell plugs CP may be formed in the entire region of the stack structure STK. Some of the cell plugs CP formed in the entire region of the stack structure STK may be removed or become dummy cell plugs as the first and second slit trenches SIT1 and ST2 are formed. In still another example, holes for forming the first and the second slit trenches SIT1 and SIT2 and the cell plugs CP may be formed together. That is, holes for cell plugs, the first slit trenches SIT1, and the second slit trenches SIT2 may be simultaneously formed. When the holes for cell plugs, the first slit trenches SIT1, and the second slit trenches SIT2 are simultaneously formed, cell plugs CP may be formed in the holes for cell plugs before processes shown in FIG. 5C are performed.

In addition, the first and second slit trenches SIT1 and STI2 may be formed to have flat sidewalls by etching trenches having a line shape. The first and second slit trenches SIT1 and STI2 may be formed by primarily etching a plurality of holes and then secondarily etching (e.g., isotropically etching) the plurality of the holes such that the plurality of holes are connected to each other. Besides, the first and second slit trenches SIT1 and SIT2 may be formed through various etching processes as long as the first and second slit trenches SIT1 and SIT2 have features described in FIGS. 4A to 4E.

Referring to FIG. 5C, an etching process for removing the first sacrificial layer 1F exposed through the first and second slit trenches SIT1 and SIT2 may be performed. A third source layer 3S may be formed in a region in which the first sacrificial layer 1F is removed. The third source layer 3S may be formed of the same material as at least one of the first source layer 1S and the second source layer 2S. Accordingly, a source line SL may be formed, which is configured with the first to third source layers 1S to 3S.

In addition, an etching process for removing the second material layers 2M exposed through the first and second slit trenches SIT1 and SIT2 may be performed. The etching process may be performed as a wet etching process for allowing the first material layers 1M to remain and selectively removing the second material layers 2M.

Conductive layers CD may be formed in regions between the first material layers 1M, in which the second material layers 2M are removed. Because the conductive layers CD formed between the first material layers 1M are used as gate lines, the conductive layers CD may be formed of a conductive material. For example, the conductive layers CD may be formed of at least one of tungsten (W), cobalt (Co), nickel (Ni), molybdenum (Mo), silicon (Si), and poly-silicon (poly-Si).

Referring to FIG. 5D, slit material layers are respectively filled in the first slit trenches SIT1 and the second slit trenches SIT2, thereby forming first slits SI1 and second slits SI2. The slit material layer may be formed as a single layer including an insulating layer or an amorphous silicon layer, or a multi-layer including a slit insulating layer and a slit conductive layer. The slit material layers respectively filled in the first slit trenches SIT1 and the second slit trenches SIT2 may be formed of the same material, and be simultaneously formed.

The conductive layers CD formed through the first and second slit trenches SIT1 and SIT2 may be used as gate lines. The gate lines may include a source select line SSL, word lines WL located on the source select line SSL, and a drain select line DSL located on the word lines WL. For example, a gate line adjacent to the source line SL among the gate lines may become the source select line SSL, some of gate lines stacked on the source select lines SSL among the gate lines may become first to nth word lines WL1 to WLn, and a gate line formed on the nth word line WLn among the gate lines may become the drain select line DSL. In FIG. 5D, it is illustrated that each of the source select line SSL and the drain select line DSL is configured as one gate line. However, this is merely illustrative, and does not limit the scope of the present disclosure. For example, the source select line SSL and/or the drain select line DSL may be configured with two or more gate lines.

The first material layers 1M located between the conductive layers CD used as the gate lines in the stack structure STK may be used as interlayer insulating layers ILD. The interlayer insulating layers ILD may be formed of an oxide layer (e.g., a silicon oxide layer). The interlayer insulating layers ILD may allow the gate lines to be spaced apart from each other, and allow the gate lines to be electrically insulated from each other.

Referring to FIG. 5D together with FIG. 4A, each of gate lines located in the same layer among the gate lines included in the ith memory block BLKi may extend through the first connection region CN1 and the second connection region CN2. The first gate line group GL1 located in one direction with respect to the second slits SI2 among the gate lines included in the ith memory block BLKi and the second gate line group GLG2 located in the opposite direction with respect to the second slits SI2 may be connected to each other by the connection region CN. For example, word lines located in the same layer among the word lines WL included in the ith memory block BLKi extend through the connection region CN (e.g., a first connection region CN1w and a second connection region CN2w), and hence conductivity can be maintained on the word lines located in the same layer. In another example, the drain select line DSL included in the ith memory block BLKi extends through the connection region CN (e.g., a first connection region CN1d and a second connection region CN2d), and hence conductivity can be maintained on the drain select line DSL. In still another example, the source select line SSL included in the ith memory block BLKi extends through the connection region CN (e.g., a first connection region CN1s and a second connection region CN2s), and hence conductivity can be maintained on the source select line SSL.

Thus, in accordance with an embodiment of the present disclosure, gate lines (e.g., word lines WL) located in the same layer are electrically connected to each other while preventing or reducing wafer warpage by adjusting the tensile stress applied to the gate lines through the second slits SI2, so that memory cells for each layer can be controlled using one gate line (e.g., one word line WL) in the corresponding layer.

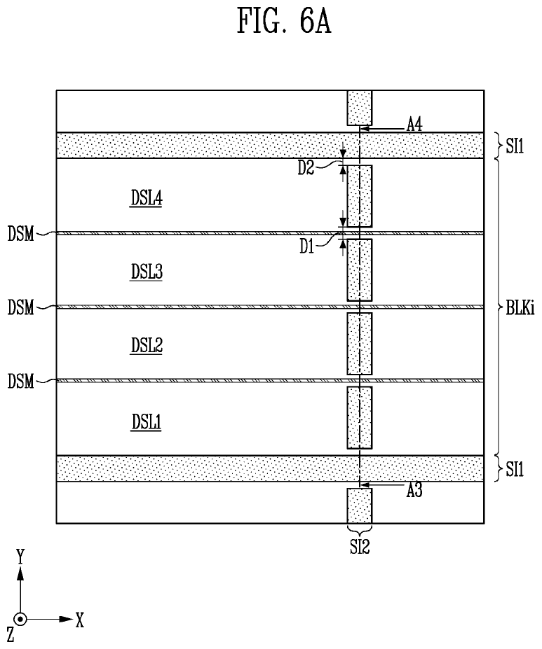

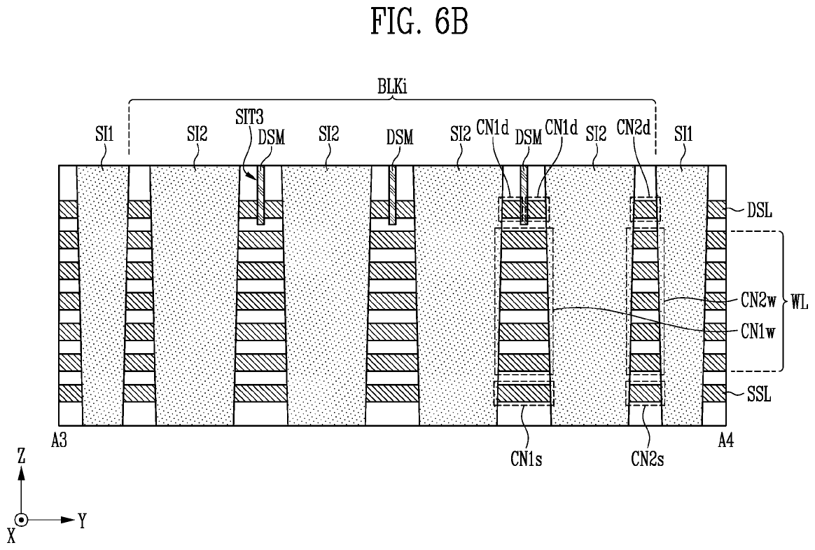

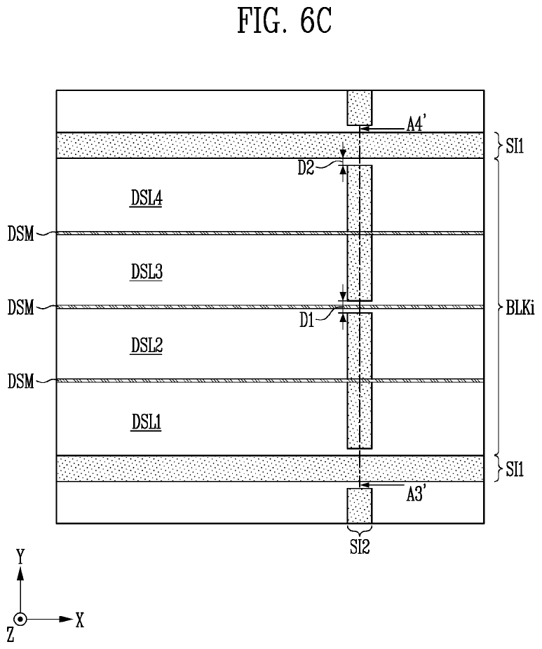

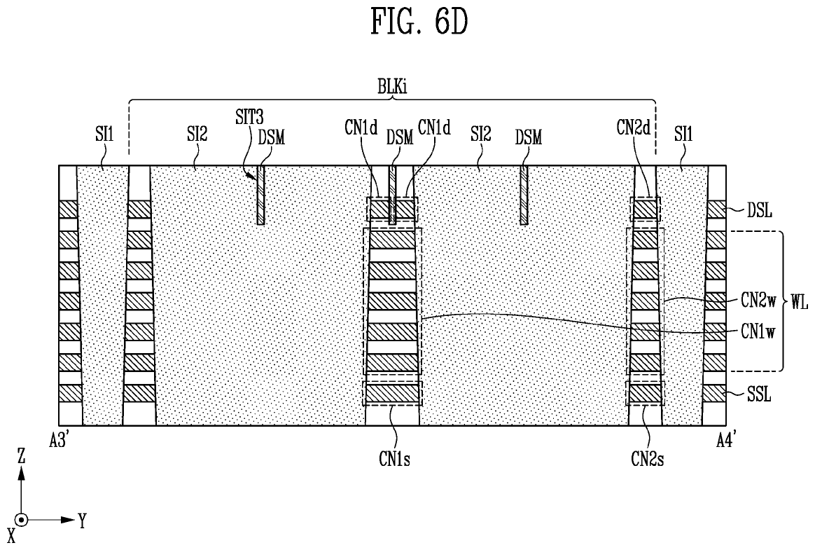

FIGS. 6A to 6D are views illustrating a structure of a memory device in accordance with a second embodiment of the present disclosure. FIG. 6B illustrates a section taken along line A3-A4 shown in FIG. 6A. FIG. 6C is a plan view illustrating an additional embodiment related to FIG. 6A. FIG. 6D illustrates a section taken along line A3′-A4′ shown in FIG. 6C.

Referring to FIG. 6A, at least one isolation pattern DSM may be formed in an ith memory block BLKi. The isolation pattern DSM may be a pattern isolating the drain select line included in the ith memory block BLKi along the first direction (e.g., the X direction). The isolation pattern DSM may extend in the first direction (e.g., the X direction).

The ith memory block BLKi may include first to fourth drain select lines DSL1 to DSL4 isolated from each other by isolation patterns DSM. The isolation patterns DSM may include an isolation insulating layer for isolating the drain select line DSL into two or more drain select lines (e.g., the first to fourth drain select lines DSL1 to DSL4). The drain select line DSL may be isolated into the first drain select line DSL1, the second drain select line DSL2, the third drain select line DSL, and the fourth drain select line DSL4, which are sequentially arranged along the second direction (e.g., the Y direction) by the isolation patterns DSM.

Second slits SI2 may be formed to be spaced apart from each other at a first distance D1 in the second direction (e.g., the Y direction). Also, the second slits SI2 may be formed to be spaced apart from a first slit SI1 at a second distance D2. The isolation patterns DSM may be formed not to overlap with the second slits SI2 spaced apart from each other between the second slits SI2.

Referring to FIG. 6B, the isolation pattern DSM may be formed to a depth to which the drain select line DSL can be isolated. For example, after the slit material layers are formed in the second slit trenches SIT2 as described in FIG. 5D, third slit trenches SIT3 may be formed, which isolates some of the conductive layers CD described in FIG. 5C along the first direction (e.g., the X direction). In addition, an insulating layer may be formed in the third slit trenches SIT3. The insulating layer formed in each of the third slit trenches SIT3 may correspond to the isolation pattern DSM.

Therefore, each of word lines WL located in the same layer among the gate lines included in the ith memory block BLKi may extend through a connection region CN (e.g., a first connection region CN1w and a second connection region CN2w). That is, the word lines WL included in the ith memory block BLKi may be electrically connected to each other through the connection region CN. In addition, the source select lines SSL among the gate lines included in the ith memory block BLKi may also extend through a connection region CN (e.g., a first connection region CN1s and a second connection region CN2s).

The drain select line DSL among the gate lines included in the ith memory block BLKi may also extend through a connection region CN. For example, the first drain select line DSL1 or the fourth drain select line DSL4 may extend through a second connection region CN2d between the first slit SI1 and the second slits SI2 and a first connection region CN1d between the second slits SI2 and the isolation pattern DSM. In addition, the second drain select line DSL2 or the third drain select line DSL3 may extend through the first connection region CN1d between the second slits SI2 and the isolation pattern DSM.

Referring to FIG. 6C, some of the isolation patterns DSM may be formed not to overlap with second slits SI2 spaced apart from each other between the second slits SI2, and others of the isolation patterns DSM may be formed to overlap with the second slits SI2.

Referring to FIG. 6D, each of word lines WL located in the same layer among the gate lines included in the ith memory block BLKi may extend through the connection region CN (e.g., the first connection region CN1w and the second connection region CN2w). The source select line SSL included in the ith memory block BLKi may also extend through connection region CN (e.g., the first connection region CN1s and the second connection region CN2s). In addition, the drain select line DSL included in the ith memory block BLKi may extend through the connection region CN. For example, the first drain select line DSL1 or the fourth drain select line DSL4 may extend through the second connection region CN2d between the first slit SI1 and the second slits SI2. In addition, the second drain select line DSL2 or the third drain select line DSL3 may extend through the first connection region CN1d between the second slits SI2 and the isolation pattern DSM.

Thus, like the first embodiment, even when the isolation pattern DSM is formed in accordance with the second embodiment, gate lines located in the same layer are electrically connected to each other while preventing or mitigating wafer warpage, using the second slits SI2, so that memory cells for each layer can be controlled using one gate line in the corresponding layer.

Although a case where three isolation patterns DSM are formed in one memory block is illustrated in FIGS. 6A to 6D, this is provided for convenience of description, and the number of isolation patterns DSM does not limit the scope of the present disclosure.

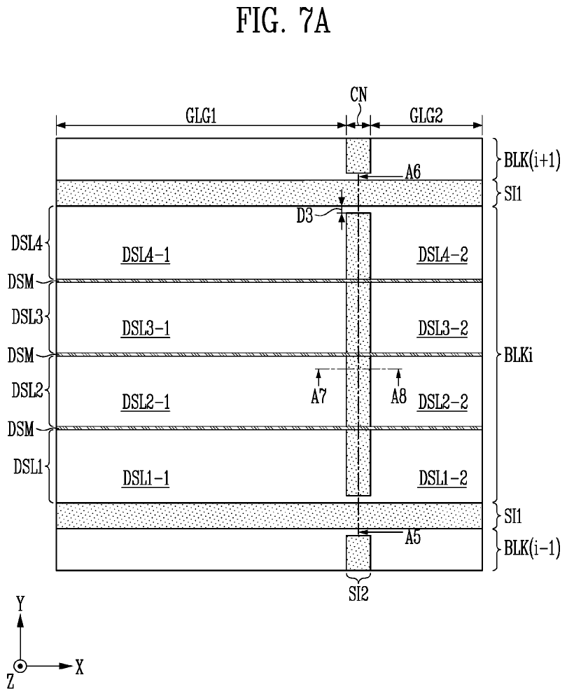

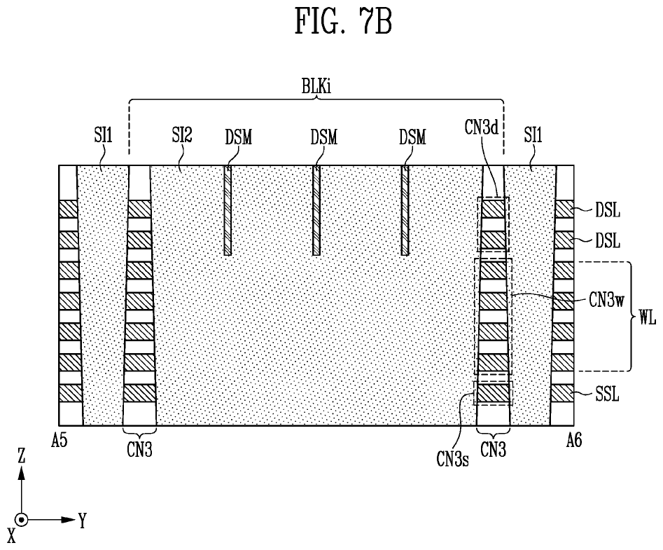

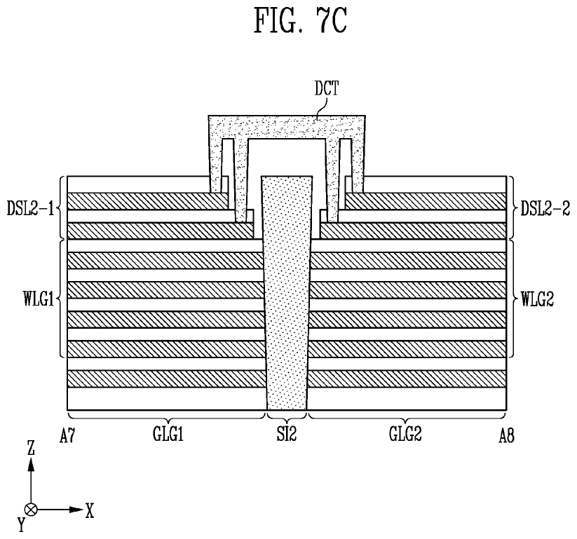

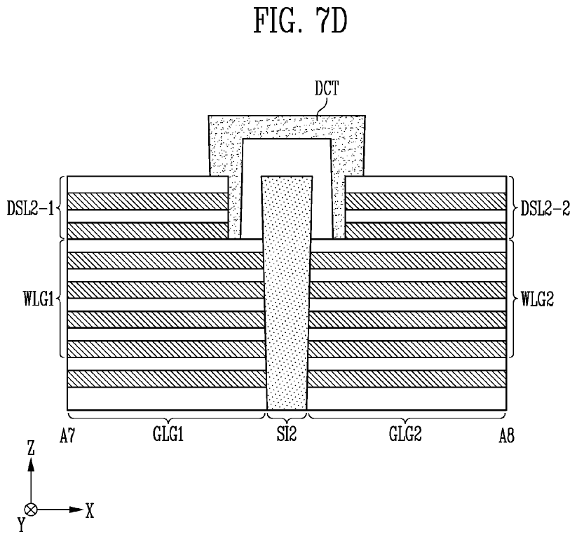

FIGS. 7A to 7D are views illustrating a structure of a memory device in accordance with a third embodiment of the present disclosure. FIG. 7A is a plan view illustrating a first slit SI1 and a second slit SI2, which are included in the memory device in accordance with the third embodiment of the present disclosure. FIG. 7B is a sectional view illustrating a section taken along line A5-A6 shown in FIG. 7A. FIGS. 7C and 7D are sectional views illustrating sections taken along line A7-A8 shown in FIG. 7.

Although the illustration is omitted in FIG. 7A, an ith memory block BLKi may include a plurality of cell plugs CP formed in the vertical direction (e.g., the Z direction) from a substrate as shown in FIG. 4B. Referring to FIG. 7A, (i−1) th to (i+1) th memory blocks BLK (i−1) to BLK (i+1) may be isolated from each other by first slits SI1. The first slit SI1 may be formed in the vertical direction (e.g., the Z direction) from a substrate, and extend in the first direction (e.g., the X direction). The first slit SI1 described in FIGS. 7A to 7D may be substantially the same component as the first slit SI1 described in FIGS. 4A to 4C.

Referring to FIGS. 7A and 7B, a second slit SI2 included in the ith memory block BLKi may penetrate the ith memory block BLKi between the first slits SI1. The second slit SI2 may be formed in the vertical direction (e.g., the Z direction) from the substrate, to penetrate the ith memory block BLKi. The first slit SI1 and the second slit SI2, which penetrate the ith memory block BLKi in the vertical direction (e.g., the Z direction), may have the same depth. Apart from two or more second slits SI2 disposed in alignment with each other along the Y direction are formed at specific positions of one memory block on an X axis in the first embodiment described in relation to FIGS. 4A to 4E, according to FIGS. 7A and 7B, one second slit SI2 may be formed at a specific position of one memory block (e.g., the ith memory block BLKi) on the X axis.

The second slit SI2 may have a plane including a minor axis in the first direction (e.g., the X direction) and a major axis in the second direction (e.g., the Y direction). For example, the second slit SI2 may be formed in a quadrangular pillar shape or a circular pillar shape.

Also, the second slit SI2 may include a slit material layer. Descriptions of the second slits SI2 shown in FIGS. 4A to 4E may be applied to the slit material layer included in the second slit SI2.

The second slit SI2 may be arranged to be spaced apart from the first slit SI1. For example, the second slit SI2 may be spaced from the first slit SI1 at a third distance D3. Because the first slit SI1 and the second slit SI2 are arranged to be spaced apart from each other, each of gate lines located in the same layer among gate lines included in each of plurality of memory blocks may extend through a third connection region CN3. For example, gate lines included in a first gate line group GLG1 among gate lines included in the ith memory block BLKi may respectively extend to gate lines included in a second gate line group GLG2 among the gate lines included in the ith memory block BLKi.

The gate lines may include a source select line SSL, word lines WL located on the source select line SSL, and drain select lines DSL located on the word lines WL. Each of word lines WL located in the same layer among the gate lines included in the ith memory block BLKi may extend through a third connection region CN3w. The source select line SSL among the gate lines included in the ith memory block BLKi may extend through a third connection region CN3s. In addition, some drain select lines DSL (e.g., DSL1 and DSL4) among the gate lines included in the ith memory block BLKi may extend through a third connection region CN3d. However, other drain select lines DSL (e.g., DSL2 and DSL3) among the gate lines included in the ith memory block BLKi might not extend through the third connection region CN3.

Referring to FIG. 7A, at least one isolation pattern DSM isolating the drain select lines DSL along the first direction (e.g., the X direction) may be formed in the ith memory block BLKi. A partial region of the isolation pattern DSM may overlap with the second slit SI2. The drain select lines DSL may be isolated into first drain select lines DSL1, second drain select lines DSL2, third drain select lines DSL3, and fourth drain select lines DSL4, which are sequentially arranged along the second direction (e.g., the Y direction), by the isolation pattern DSM.

Because the second slit SI2 is formed to be spaced apart from the first slit SI1 at the third distance D3, some of the drain select lines DSL included in the ith memory block BLKi may extend through the third connection region CN3. The first drain select lines DSL1 or the fourth drain select lines DSL4 may extend through the third connection region CN3d between the first slit SI1 and the second slit SI2. For example, the first drain select lines DSL1 may include (1-1) th drain select lines DSL1-1, (1-2) th drain select lines DSL1-2 adjacent to the (1-1) th drain select lines DSL1-1 in the first direction (e.g., the X direction) with the second slit SI2 interposed therebetween, and the third connection region CN3d connecting the (1-1) th drain select lines DSL1-1 and the (1-2) th drain select lines DSL1-2 to each other.

However, the second drain select lines DSL2 or the third drain select lines DSL3 might not extend through the third connection region CN3 between the first slit SI1 and the second slit SI2. For example, the second drain select lines DSL2 may include (2-1) th drain select lines DSL2-1 and (2-2) th drain select lines DSL2-2 adjacent to the (2-1) th drain select lines DSL2-1 in the first direction (e.g., the X direction) with the second slit SI2 interposed therebetween, and the (2-1) th drain select lines DSL2-1 and the (2-2) th drain select lines DSL2-2 may be isolated from each other by the second slit SI2. A method of electrically connecting drain select lines (e.g., the second and third drain select lines DSL2 and DSL3) isolated from each other by the second slit SI2 will be described in FIGS. 7C and 7D.

Referring to FIG. 7C, the second gate line group GLG2 may represent gate lines located in the first direction (e.g., the X direction) with respect to the second SI2, and the first gate line group GLG1 may represent gate lines located in the opposite direction of the first direction with the second slit SI2. The second drain select lines DSL2 included in the ith memory block BLKi may include the (2-1) th drain select lines DSL2-1 included in the first gate line group GLG1 and the (2-2) th drain select lines DSL2-2 included in the second gate line group GLG2. In addition, the word lines WL included in the ith memory block BLKi may include a first word line group WLG1 included in the first gate line group GLG1 and a second word line group WLG2 included in the second gate line groups GLG2.

As described with reference to FIGS. 7A and 7B, because the first word line group WLG1 and the second word line group WLG2 extend to each other through the third connection region CN3, the first word line group WLG1 and the second word line group WLG2 may be electrically connected to each other. However, because the (2-1) th drain select lines DSL2-1 and the (2-2) th drain select lines DSL2-2 are isolated from each other by the second slit SI2, the (2-1) th drain select lines DSL2-1 and the (2-2) th drain select lines DSL2-2 might not extend to each other.

Referring to FIG. 7C, the memory device may include a drain contact structure DCT electrically connecting the (2-1) th drain select lines DSL2-1 and the (2-2) th drain select lines DSL2-2 to each other. A portion of the drain contact structure DCT may be in contact with the (2-1) th drain select lines DSL2-1, and another portion of the drain contact structure DCT may be in contact with the (2-2) th drain select lines DSL2-2. For example, when each of the second drain select lines DSL2 is configured with two or more gate lines, the drain contact structure DCT may include four or more pillar structures respectively in contact with (2-1) th drain select lines DSL2-1 in each layer and (2-2) th drain select lines DSL2-2 in each layer. In addition, the (2-1) th drain select lines DSL2-1 and the (2-2) th drain select lines DSL2-2, each of which includes two or more gate lines, may be formed in a stepped structure in which gate lines in each layer form one step.

Referring to FIG. 7D, the other components except a shape of the drain contact structure DCT are identical to those described with reference to FIG. 7C. Therefore, in FIG. 7D, descriptions of structures overlapping with those shown in FIG. 7C will be omitted or simplified.

Referring to FIG. 7D, the drain contact structure DCT may include a pillar structure which is not in contact with each of the two or more (2-1) th drain select lines DSL2-1 but in contact with the (2-1) th drain select lines DSL2-1 together. For example, the drain contact structure DST may include two pillar structures, and one of the pillar structures may be in contact with the (2-1) th drain select lines DSL2-1, and the other of the pillar structures may be in contact with the (2-2) th drain select lines DSL2-2. In addition, the (2-1) th drain select lines DSL2-1 and the (2-2) th drain select lines DSL2-2, each of which includes two or more gate lines, may be formed in a stepped structure in which the two or more gate lines form one step.

The shapes of the drain contact structure DCT, described in FIGS. 7C and 7D, are merely illustrative. Besides, the drain contact structure DCT may have various shapes capable of electrically connecting the (2-1) th drain select lines DSL2-1 and the (2-2) th drain select lines DSL2-2 to each other.

In accordance with the third embodiment of the present disclosure, the tensile stress in the X direction, which is applied to each of the gate lines, can be further decreased. In an embodiment, when the second slit SI2 is formed in a line shape in which second slits are connected into one instead of a shape in which second slits are spaced apart from each other, the tensile stress in the X direction is further decreased, so that the warpage of a wafer can be reduced.

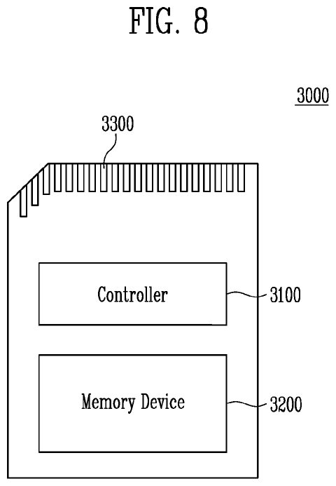

FIG. 8 is a diagram illustrating a memory card system to which the memory device of the present disclosure is applied.

Referring to FIG. 8, the memory card system 3000 includes a controller 3100, a memory device 3200, and a connector 3300.

The controller 3100 may be connected to the memory device 3200. The controller 3100 may access the memory device 3200. For example, the controller 3100 may control a program, read or erase operation, or control a background operation of the memory device 3200. The controller 3100 may provide an interface between the memory device 3200 and a host. The controller 3100 may drive firmware for controlling the memory device 3200. For example, the controller 3100 may include components such as a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may communicate with the external device through at least one of various communication protocols such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication protocols.

The memory device 3200 may include memory cells and may be configured identically to the memory device 100 shown in FIG. 1.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

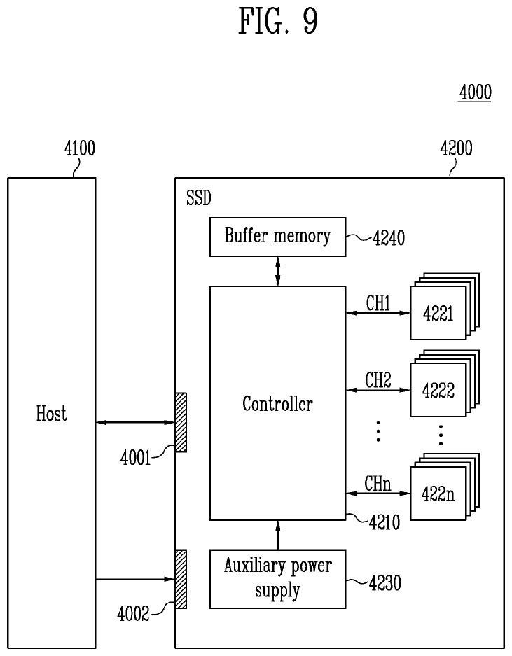

FIG. 9 is a diagram illustrating a Solid State Drive (SSD) system to which the memory device of the present disclosure is applied.

Referring to FIG. 9, the SSD system 4000 may include a host 4100 and an SSD 4200. The SSD 4200 may exchange a signal with the host 4100 through a signal connector 4001, and receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may be a signal based on an interface between the host 4100 and the SSD 4200. For example, the signal may be a signal defined by at least one of interfaces such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power input from the host 4100 and charge the power. When the supply of power from the host 4100 is not smooth, the auxiliary power supply 4230 may provide power of the SSD 4200. For example, the auxiliary power supply 4230 may be located in the SSD 4200, or be located at the outside of the SSD 4200. For example, the auxiliary power supply 4230 may be located on a main board, and provide auxiliary power to the SSD 4200.

The buffer memory 4240 may operate as a buffer memory of the SSD 4200. For example, the buffer memory 4240 may store data received from the host 4100 or data received from the plurality of memory devices 4221 to 422n, or store meta data (e.g., a mapping table) of the memory devices 4221 to 422n. The buffer memory 4240 may include volatile memories such as a DRAM, an SDRAM, a DDR SDRAM, an LPDDR SDRAM, and a GRAM or nonvolatile memories such as a FRAM, a ReRAM, an STT-MRAM, and a PRAM.

In accordance with the present disclosure, warpage of the memory device is prevented or mitigated, so that defects which may occur in the memory device can be reduced.

While the present disclosure has been shown and described with reference to certain examples of embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described examples of embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A memory device comprising:
a memory cell array including a plurality of cell plugs;
a first slit isolating the memory cell array into a plurality of memory regions, the first slit extending in a first direction; and
second slits penetrating the plurality of memory regions, the second slits being arranged to be spaced apart from each other in a second direction intersecting the first direction,
wherein gate lines included in each of the plurality of memory regions are isolated from each other by the first slit, and
wherein each gate line located in the same layer among the gate lines included in each of the plurality of memory regions extends through a first connection region between the second slits for each corresponding memory region.

2. The memory device of claim 1, wherein each of the second slits is formed in substantially a quadrangular pillar shape or substantially a circular pillar shape.

3. The memory device of claim 1, wherein a plane of each of the second slits includes a minor axis in the first direction and a major axis in the second direction.

4. The memory device of claim 1, further including a second connection region between the first slit and the second slits.

5. The memory device of claim 4, wherein each of gate lines located in the same layer among the gate lines included in each of the plurality of memory regions extends through the first connection region and the second connection region.

6. The memory device of claim 5, wherein the gate lines included in each of the plurality of memory regions include:
a source select line;
word lines located on the source select line; and
a drain select line located on the word lines.

7. The memory device of claim 6, further comprising an isolation pattern isolating the drain select line along the first direction.

8. The memory device of claim 1, further comprising third slits spaced apart from the second slits in the first direction, the third slits penetrating the plurality of memory regions.

9. The memory device of claim 8, wherein the third slits are spaced apart from each other in the second direction.

10. The memory device of claim 8, wherein each of the third slits is formed in substantially a quadrangular pillar shape or substantially a circular pillar shape.

11. The memory device of claim 8, wherein a plane of each of the third slits includes a minor axis in the first direction and a major axis in the second direction.

12. The memory device of claim 1, wherein each of the first and second slits is formed as a single layer or a multi-layer.

13. A method of manufacturing a memory device, the method comprising:
forming a stack structure in which first material layers and second material layers are alternately stacked;
forming cell plugs penetrating the stack structure;
forming first slit trenches isolating the stack structure along a first direction and second slit trenches which are spaced apart from each other in a second direction intersecting the first direction between the first slit trenches and penetrate the stack structure;
removing the second material layers exposed through the first slit trenches and the second slit trenches;
forming conductive layers in regions between the first material layers, in which the second material layers are removed; and
forming a slit material layer in the first and second slit trenches.

14. The method of claim 13, wherein the first slit trenches and the second slit trenches are formed to have substantially the same depth.

15. The method of claim 13, wherein the second slit trenches are formed to be spaced apart from the first slit trenches.

16. The method of claim 13, wherein the slit material layer is a single layer including an insulating layer or a silicon layer.

17. The method of claim 13, wherein the forming of the slit material includes:
forming a slit insulating layer along side surfaces of the first and second slit trenches; and
forming a slit conductive layer inside the first and second slit trenches in which the slit insulating layer is formed.

18. The method of claim 13, further comprising:
after the forming of the slit material layer,
forming a third slit trench isolating a portion of the conductive layers along the first direction; and
forming an isolation insulating layer in the third slit trench.
